(19) United States
(12) Patent Application Publication
(10) Pub. No.: US 2023/0174689 A1
(43) Pub. Date: Jun. 8, 2023

(54) POLYMER

(71) Applicant: Sumitomo Chemical Co., Ltd., Tokyo (JP)

(72) Inventors: Florence Bourcet, Godmanchester (GB); Jonathan Pillow, Godmanchester (GB); Martin Humphries, Godmanchester (GB)

(73) Assignee: Sumitomo Chemical Co., Ltd., Tokyo (JP)

(21) Appl. No.: 17/916,211

(22) PCT Filed: Mar. 31, 2021
(86) PCT No.: PCT/EP2021/058512

§ 371 Date: Sep. 30, 2022

(30) Foreign Application Priority Data
Mar. 31, 2020 (GB) 2004746.0

(51) Int. Cl. C08F 36/04; C08F 2/48; C08F 2/06; C09K 11/06

(52) U.S. Cl. CPC C08F 36/04; C08F 2/48; C08F 2/06; C09K 11/06; C08F 2438/00; C09K 2211/1475

(57) ABSTRACT

A light-emitting polymer comprising a repeat unit of formula (I): R¹-R⁴ are each independently H or a substituent; and Ar¹ and Ar² are each independently an aromatic or heteroaromatic group selected from formulae (IIa) and (IIb): The polymer may be formed from a non-luminescent or weakly luminescent monomer.

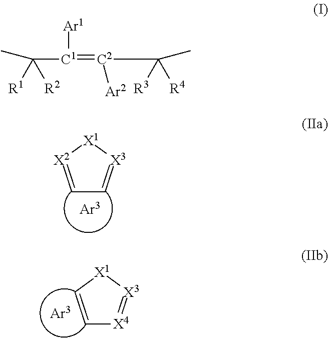

### BACKGROUND

Embodiments of the present disclosure relate to light-emitting polymers and methods and monomers for forming light-emitting polymers.

Mueller et al, “Fluorescent polymers from non-fluorescent photoreactive monomers” discloses fluorescent polymers formed by a nitrile imine-mediated tetrazole-ene cycloaddition (NITEC) process.

JP H05-165142 discloses a copolymer of the following compounds:

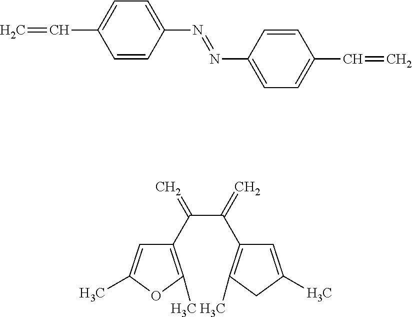

KR1020140132842 discloses compounds for use in dye-sensitized solar cells.

### SUMMARY

In some embodiments, the present disclosure provides a light-emitting polymer comprising a repeat unit of formula (I):

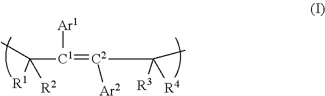

wherein:
R¹-R⁴ are each independently H or a substituent; and
Ar¹ and Ar² are each independently an aromatic or heteroaromatic group selected from formulae (IIa) and (IIb):

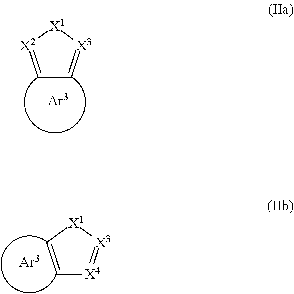

wherein:
X¹ is O, S, NR⁵ or PR⁵;
X²-X⁴ independently in each occurrence is selected from CR⁶ and N;
R⁵ is H or a substituent;
R⁶ independently in each occurrence is H, a substituent or a direct bond to C¹ or C²;
Ar³ is an aromatic or heteroaromatic group; and either:
one of X²-X⁴ is CR⁶ wherein R⁶ is a direct bond to C¹ or C²; or
an aromatic carbon atom of Ar³ is bound directly to C¹ or C².

Optionally, R¹-R⁴ are each H.

Optionally, Ar³ is benzene which is unsubstituted or substituted with one or more substituents.

Optionally, the polymer is a copolymer comprising a repeat unit of formula (I) and at least one co-repeat unit.

Optionally, the polymer comprises a co-repeat unit of formula (III):

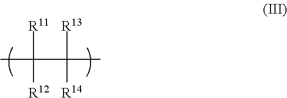

wherein R¹¹-R¹⁴ independently in each occurrence is H or a substituent.

In some embodiments, the present disclosure provides a method of forming a polymer comprising polymerisation of a monomer of formula (Im):

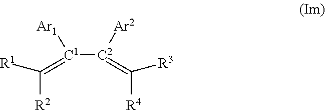

wherein Ar¹, Ar² and R¹-R⁴ are as described above.

Optionally, the polymerisation is a radical polymerisation.

Optionally, the polymerisation is an ionic polymerisation.

In some embodiments, the present disclosure provides a composition comprising:

a compound of formula (Im) as described herein; and
an initiator for forming, upon irradiation with light of a write wavelength, a reactive material for initiating polymerisation of the compound of formula (Im).

Optionally, the composition further comprising an inhibitor for inhibiting formation of the reactive material upon irradiation with light of a write inhibition wavelength.

In some embodiments, the present disclosure provides a method of recording data to a layer of a recording medium comprising a composition as described herein, the method comprising irradiating the composition with a first light beam having the write wavelength. Optionally according to this method, the composition comprises an inhibitor for inhibiting formation of the reactive material upon irradiation with light of a write inhibition wavelength; the composition is irradiated with a second light beam having the write inhibition wavelength; the second light beam has a central area and a surrounding area; an intensity of the second light beam in the central area is lower than an intensity of the second light beam in the surrounding area; the first light beam extends across the central area; and the surrounding area of the second light beam surrounds the first light beam.

### DESCRIPTION OF DRAWINGS

FIG. 1A is a schematic illustration of irradiation of a recording medium with first and second light beams to write data to the recording medium according to some embodiments of the present disclosure;

FIG. 1B is a cross-section through plane A-A of the first and second light beams of FIG. 1A;

FIG. 1C is a plot of intensity vs distance for first and second light beams according to some embodiments; and

FIG. 2 is a plot showing a change in photoluminescence upon irradiation of a composition according to some embodiments and of a comparative composition.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology.

Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details. The present inventors have identified monomers which, upon polymerisation, form repeat units which may emit light. The monomer may emit light at a much lower intensity than a polymer containing a repeat unit formed from the monomer.

The light-emitting polymers described herein may be used to provide photoluminescent properties at 20° C. to commodity polymers and products containing a polymer which, in the absence of the repeat units described herein, may emit little or no light. The light-emitting polymers described herein may be used for, without limitation, fluorescent labelling of polymers, e.g. for visual differentiation between different polymers; fluorescent polymers for clothing or footwear including, without limitation, fluorescent PVC for shoe soles and fluorescent polyacrylic for clothing; and fluorescent styrene-butadiene for rubber products, e.g. tyres.

The monomers described herein may be used in a data recording medium. Upon writing to the medium, a non-luminescent, or weakly luminescent, monomer may polymerise to a luminescent polymer.

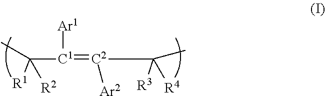

R¹-R⁴ are each independently H or a substituent.
Ar¹ and Ar² are each independently an aromatic or heteroaromatic group selected from formulae (IIa) and (IIb):

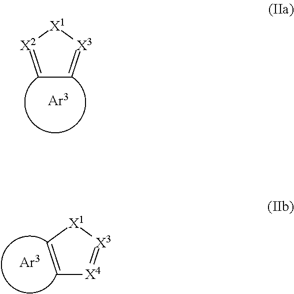

X¹ is O, S, NR⁵ or PR⁵ wherein R⁵ is H or a substituent.

X²-X⁴ independently in each occurrence is selected from CR⁶ and N wherein R⁶ independently in each occurrence is H, a substituent or a direct bond to C¹ or C².

Ar³ is an aromatic or heteroaromatic group which is unsubstituted or substituted with one or more substituents, for example one or more substituents R⁷ as described below.

The group of formula (IIa) or (IIb) is bound to C¹ or C² by a direct carbon-carbon bond. One of X²-X⁴ is a carbon bound directly to C¹ or C², or an aromatic carbon atom of Ar³ is bound directly to C¹ or C².

Further, the present inventors have found that such light-emitting polymers may be formed from monomers which have relatively little or no luminescence. The light-emitting polymers may be formed by polymerisation of a monomer of formula (Im), either alone or with one or more co-monomers:

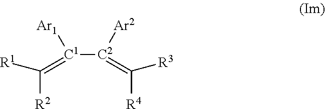

The polymer preferably has higher luminance at 20° C., optionally higher by at least a factor of 10, upon irradiation at the longest absorption wavelength peak of the polymer as compared to luminance of the monomer or monomers from which the repeat unit of formula (I) is formed upon irradiation of the monomer for forming the repeat unit of formula (I), and any co-monomers, at the longest absorption wavelength peak or peaks of the monomer or monomers.

Preferably, the polymer has a longer peak emission wavelength than any peak emission wavelength of the monomer for forming the repeat unit of formula (I) or any co-monomers.

Optionally, the polymer has a peak emission wavelength in the range of 350-800 nm.

The fluorescence spectrum of the light-emitting polymer may be as measured using an Ocean Optics 2000+ spectrometer.

Preferably, Ar³ is benzene which is unsubstituted or substituted with one or more substituents.

Exemplary groups of formula (IIa) are:

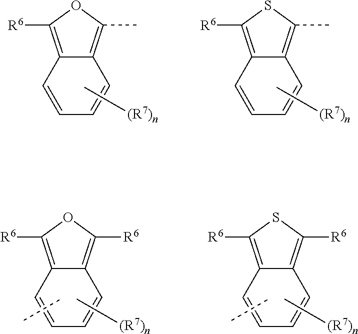

wherein R⁵ and R⁶ are each independently H or a substituent; R⁷ independently in each occurrence is a substituent; m is 0, 1, 2 or 3; n is 0, 1, 2, 3 or 4; and --- represents direct bond to C¹ or C².

Optionally, R⁶ groups which are not H or a direct bond and R⁷ groups (where present) are each independently selected from the group consisting of F; CN; NO₂; and C₁₋₂₀ alkyl wherein one or more non-adjacent, non-terminal C atoms may be replaced with O, S, CO or COO and wherein one or more H atoms of the alkyl may be replaced with F.

Exemplary groups of formula (IIb) are:

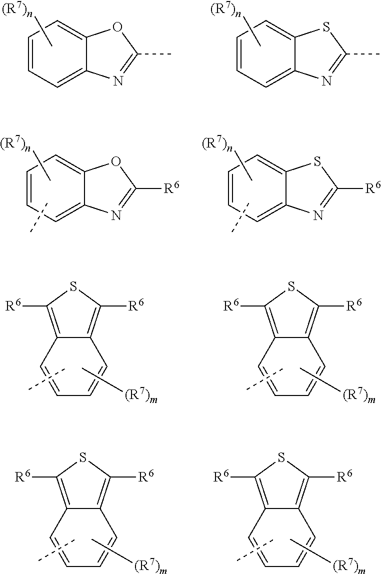

Preferably, the aromatic carbon atom or atoms of the group of formula (IIa) or (IIb) which are adjacent to the carbon atom bound to C¹ or C² are unsubstituted.

Polymers comprising a repeat unit of formula (I) may be homopolymers or copolymers comprising one or more repeat units of formula (I) and one or more co-repeat units.

Optionally, 0.1-50 mol % or 0.1-10 mol % of the repeat units of such a copolymer are repeat units of formula (I).

Preferably, luminance of such a copolymer at 20° C. upon irradiation at its longest wavelength absorption peak is greater than, preferably at least 10 times greater than, luminance of a comparative polymer in which the repeat units of formula (I) are absent upon irradiation at the longest wavelength absorption peak of the comparative polymer. Preferably, the comparative polymer in which repeat units of formula (I) are not present is not luminescent at 20° C.

Optionally, the repeat unit of formula (I) is the only repeat unit of the polymer containing an unsaturated carbon-carbon bond in the polymer backbone.

Preferably, the repeat unit of formula (I) is the repeat unit having the greatest extent of conjugation of the polymer. Preferably, the repeat unit of formula (I) is the only repeat unit of the polymer containing a non-aromatic carbon-carbon double bond conjugated directly to two aromatic or heteroaromatic groups.

Optionally, the repeat unit of formula (I) has the lowest singlet excited state energy (S₁) level of the repeat units of any such co-polymer. This may be determined by measuring the S1 level of a copolymer containing repeat units of formula (I) from the fluorescence spectrum thereof and comparing it to a polymer in which repeat units of formula (I) are absent.

Exemplary co-repeat units include repeat units of formula (III):

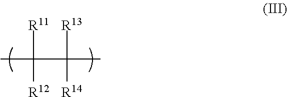

Wherein R¹¹ and R¹² are each independently H or a substituent and R³ and R¹⁴ are each H or F.

Co-repeat units of formula (III) may be formed by polymerisation of a monomer of formula (IIIm):

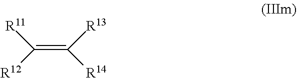

In some embodiments, R¹¹ and R¹² are selected from the group consisting of H, F, Cl, COOR⁹ wherein R⁹ is H or a substituent; CN; C₁₋₂ alkyl; H₂C═CR¹⁵— wherein R¹⁵ is H or a substituent; and aryl or heteroaryl which is unsubstituted or substituted with one or more substituents.

Optionally, an aryl or heteroaryl groups R¹¹ or R¹² is phenyl which is unsubstituted or substituted with one or more substituents selected from C₁₋₁₂ alkyl wherein one or more non-adjacent, non-terminal H atoms may be replaced with O, S, CO or COO.

Optionally, R⁹ is selected from C₁₋₁₂ alkyl and phenyl which is unsubstituted or substituted with one or more C₁₋₂ alkyl groups.

Optionally, R¹⁵ is selected from H and C₁₋₁₂ alkyl.

Exemplary monomers of formula (III) include ethylene, propylene, vinyl chloride, styrene, acrylic acid, methacrylic acid, methyl cyanoacrylate, vinylidene fluoride and butadiene repeat units.

Polymers as described herein may be formed by any suitable method known to the skilled person including, without limitation, cationic, anionic or radical polymerisation.

Radical polymerisation may be free radical polymerisation or controlled radical polymerisation. Controlled radical polymerisation is optionally selected from Atom Transfer Radical Polymerization (ATRP); Reversible Addition/Fragmentation Chain Transfer Polymerization (RAFT); and Nitroxide-mediated Polymerization (NMP).

The light-emitting polymer may be used to write data to a recording medium. The recording medium may take any form configured to be written to by a writing apparatus, for example a disc. The disc may contain a single writeable layer or may contain two or more writeable layers. The disc may be single sided or double sided.

In some embodiments, an organic luminescent precursor composition containing a monomer of formula (Im), optionally with one or more co-monomers, irradiated in selected regions with light having a write wavelength to cause the monomer(s) to polymerise in those regions.

Optionally, the organic luminescent precursor composition contains an initiator for initiating a free radical polymerisation and which is activated upon irradiation at a write wavelength.

In some embodiments, data is written by a 2-photon absorption method. Two-photon absorption is described in “Three-Dimensional Microfabrication Using Two-Photon Polymerisation”, Ed. Tommaso Baldacchini, Elsevier 2016, the contents of which are incorporated herein by reference.

Because optical transition rate due to 2-photon absorption depends on the square of the light intensity, it is particularly suited to writing to two or more layers of a recording medium.

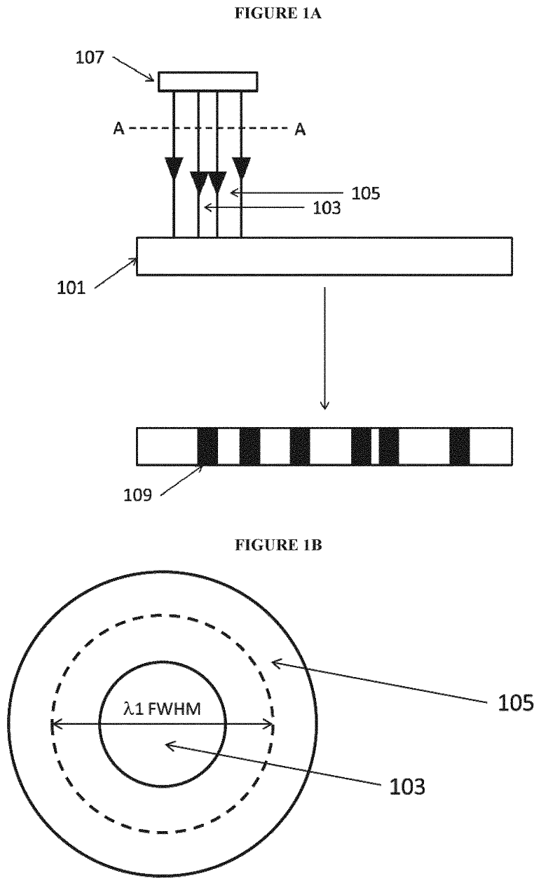

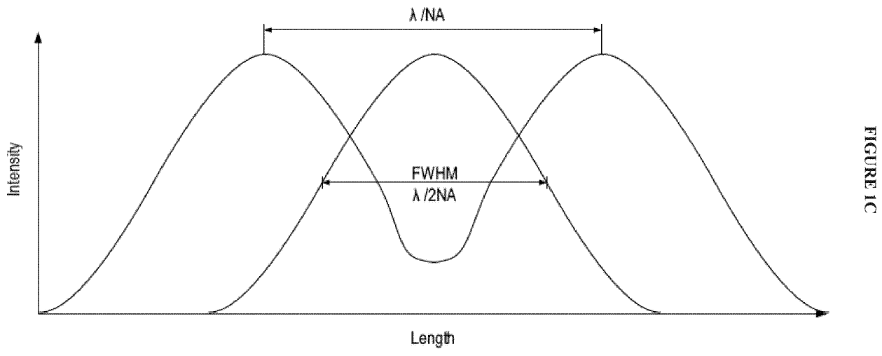

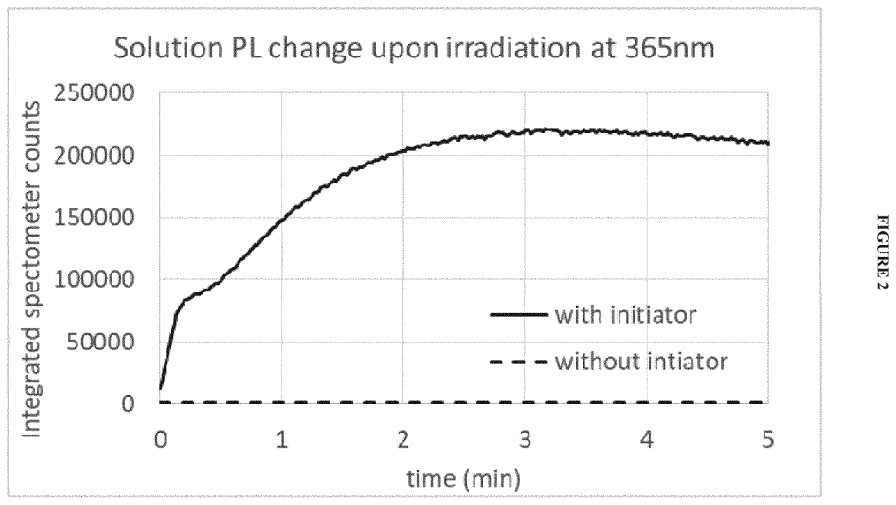

FIG. 1A schematically illustrates conversion of an organic luminescent precursor composition containing a monomer of formula (Im) to an organic luminescent material composition containing a light-emitting polymer comprising a repeat unit of formula (I). A recording medium 101 containing the organic luminescent precursor composition is irradiated by a light source 107 of the writing apparatus.

The recording medium is irradiated with write beam, e.g. laser, 103 having a first wavelength λ₁ and write inhibition beam, e.g. laser, 105 which surrounds the write beam and which has a write inhibition wavelength λ₂.

Upon irradiation by the write beam, a material of the composition may absorb two photons of the write wavelength λ1 causing excitation from a ground state, via a virtual state, to an excited state. The energy 2hc/λ₁ absorbed by the absorbing material is at least the same as or higher than that of the ground state—excited state energy gap of the material.

Intensity of the write beam to achieve 2-photon absorption is preferably at least 50 mW/cm², optionally in the range of 75-300 mW/cm².

Optionally, λ₁ is at least 600 nm, optionally at least 700 nm, optionally in the range of about 600-1000 nm.

2-photon absorption by the organic luminescent precursor composition in a region 109 which is irradiated by the write beam and which is irradiated by little or none of the light of the write inhibition beam causes conversion of the organic luminescent precursor composition to an organic luminescent composition.

The recording medium may be configured to move relative to the light-source 107, e.g. rotate, such that a plurality of regions of the recording medium is written to.

FIG. 1B illustrates a cross-section of the write beam 103 and write inhibition beam 105.

FIG. 1C illustrates intensities of the write beam 103 and write inhibition beams 105.

The write beam has a full width at half maximum (FWHM) of λ₁/2NA wherein NA is the numerical aperture of the focusing optics. This may be greater than or equal to about 200 nm, optionally greater than or equal to about 300 nm.

With reference to FIGS. 1B and 1C, the write inhibition beam has a toroidal or “doughnut” region encompassing a maximum of the write inhibition beam and surrounding a central region encompassing a minimum of the write inhibition beam. The toroidal region surrounds and overlaps the FWHM of the write beam. With reference to FIG. 1C, the peak-to-peak distance of the write inhibition beam may be λ1/NA. The width of the toroidal region may be the FWHM of the write inhibition beam.

With reference to FIG. 1C, the intensity of the write inhibition beam is at a minimum within the area defined by the FWHM of the write beam. Preferably, the minimum of the write inhibition beam is aligned with the maximum of the write beam.

In the embodiment of FIG. 1C, the minimum intensity of the write inhibition beam in the area defined by the FWHM of the write beam is a non-zero value. Optionally, intensity of light of the write inhibition beam in the central region is at least 10 times lower than anywhere in the surrounding toroidal region. In other embodiments, it is zero in at least part of the area defined by the FWHM of the write beam.

The width of the written areas (i.e. writing resolution) may be less than 100 nm, optionally less than 80 nm or less than 50 nm, optionally at least 5 or 10 nm. In this way, data may be written at below a diffraction limit of the write wavelength.

Reading apparatus configured to read data recorded on the recording medium may comprise a light source configured to emit an excitation beam onto the recording medium wherein the excitation beam has a wavelength at which the organic luminescent material luminesces.

The written recording medium may be read by stimulated emission depletion (STED) in which the excitation beam is surrounded by a deactivation beam such that only organic luminescent material irradiated by the excitation beam in a focal area emits light. The skilled person will understand how the focal area may be adjusted by altering the properties of the pupil plane of an objective lens. STED is described in more detail in, for example, Gu et al, “Nanomaterials for optical data storage”, Nature Reviews Materials, Vol 1, p. 1-14, December 2016, the contents of which are incorporated herein by reference.

### Examples

### Monomer Example 1

Monomer Example 1 was prepared according to Scheme 1:

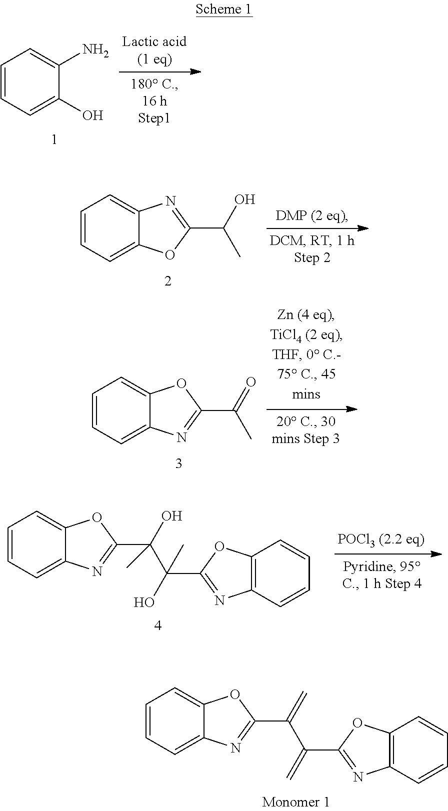 [SMILES: Nc1ccccc1O ; CC(O)c1nc2ccccc2o1 ; CC(=O)c1nc2ccccc2o1 ; CC(O)(c1nc2ccccc2o1)C(C)(O)c1nc2ccccc2o1 ; C=C(C(=C)c1nc2ccccc2o1)c1nc2ccccc2o1]

### Step 1: Synthesis of Intermediate 2

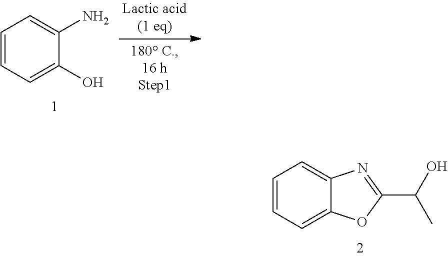

2-Aminophenol (100 g, 916 mmol) and 2-hydroxypropanoic acid (82.5 g, 916 mmol) were placed in a 500 mL round-bottomed flask equipped with a magnetic stirrer, oil-bath, condenser and nitrogen bubbler and refluxed for 16 hours at 150° C. The mixture was then heated to 180° C. 27 g of Intermediate 2 was isolated by distillation and used without further purification.

### Step 2: Synthesis of Intermediate 3

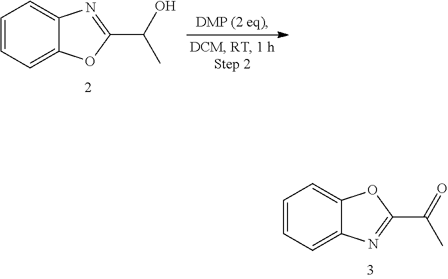

To a stirred solution of 1-(1,3-benzoxazol-2-yl)ethan-1-ol (Intermediate 2, 27 g, 165 mmol) in dichloromethane (555 mL) in a 1 L multi neck round bottomed flask equipped with a magnetic stirrer and a nitrogen bubbler was added Dess-Martin Periodinane (139 g, 327 mmol) portion-wise.

The reaction mixture was stirred at room temperature for an hour and then diluted with DCM (1 L) and passed through celite bed.

The filtrate was washed with water (500 mL) followed by sodium bicarbonate solution (1 L), filtered through celite bed and then layers were separated. The organic layer was concentrated to give crude 25 g of product which purified using a silica gel column (60-120 mesh) using DCM in hexane as an eluent.

10 g of Intermediate 3 was isolated with 99.7% LCMS purity.

¹H-NMR (400 MHz, CDC₃) δ 7.92 (dd, J=0.40 Hz, 1H), 7.67 (d, J=8.40 Hz, 11H), 7.58-7.54 (m, 1H), 7.50-7.46 (m, 1H), 2.83 (s, 3H).

### Synthesis of Intermediate 4

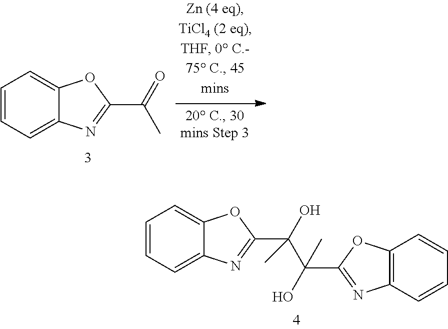 [SMILES: CC(=O)c1nc2ccccc2o1 ; CC(O)(c1nc2ccccc2o1)C(C)(O)c1nc2ccccc2o1]

TiCl₄ (16.3 mL, 148 mmol) was added to Zinc Powder (19.4 g, 297 mmol) in THF (360 mL) at 0° C. in a 1 L round-bottomed flask connected to a magnetic stirrer, condenser, oil-bath and nitrogen bubbler.

The reaction mixture was heated to 75° C. with stirring for 45 minutes and then cooled to 20° C. To the reaction mixture was added 1-(1,3-benzoxazol-2-yl)ethan-1-one (Intermediate 3, 12 g, 74.4 mmol) in THF (120 mL) at 20° C. The reaction mixture was stirred for 30 minutes and then quenched with water (1 L) and extracted with ethyl acetate (1 L). The organic layer was concentrated to give crude product 11 g, 52% purity by LCMS. The solid was taken in ethyl acetate (20 mL), stirred at 0° C. for 10 mins and filtered. 5 g of Intermediate 4 isolated with 94% HPLC purity was obtained.

### Synthesis of Monomer 1

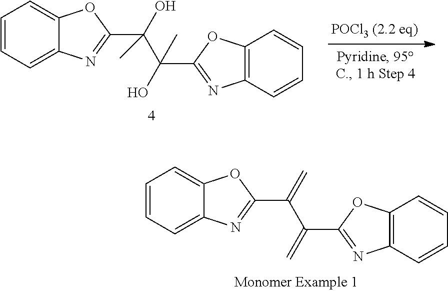 [SMILES: CC(O)(c1nc2ccccc2o1)C(C)(O)c1nc2ccccc2o1 ; C=C(C(=C)c1nc2ccccc2o1)c1nc2ccccc2o1]

2,3-bis(1,3-benzoxazol-2-yl)butane-2,3-diol (Intermediate 4, 1.3 g, 4 mmol) was taken in Pyridine (13 mL) in a 25 mL 2-neck round-bottomed flask connected to a magnetic stirrer, oil-bath, condenser and nitrogen bubbler. The reaction mixture was cooled to 0° C. and POCl₃ (0.82 mL, 8.80 mmol) was added drop-wise. The reaction mixture was then heated to 95° C. for 1.5 h. The mixture was turbid at 95° C. for 10 mins and then slowly become a clear solution. The reaction mixture was diluted with hexane (100 mL) and washed with water (150 mL) followed by 1.5 N HCl (200 mL). The hexane layer separated and concentrated to give 0.35 g of product which was purified by combi column purification using hexane/ethyl acetate as eluent. The desired product eluted at ˜10% ethyl acetate in hexane. 80 mg of Monomer 1 was isolated with 99.8% HPLC purity.

¹H-NMR (400 MHz, CDCl₃): δ 7.70-7.68 (m, 2H), 7.55-7.53 (m, 2H), 7.38-7.29 (m, 4H), 6.69 (s, 2H), 6.11 (s, 2H).

### Model Emitter 1

Model Emitter 1 was prepared according to Scheme 3.

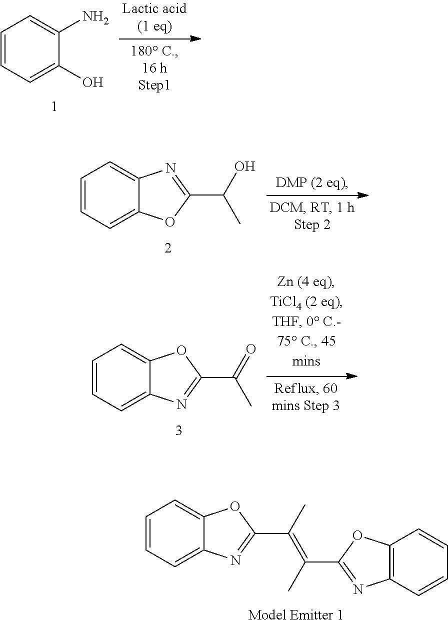 [SMILES: Nc1ccccc1O ; CC(O)c1nc2ccccc2o1 ; CC(=O)c1nc2ccccc2o1 ; C/C(=C(/C)c1nc2ccccc2o1)c1nc2ccccc2o1]

### Scheme 3

Intermediates 2 and 3 were prepared by the same method as for Monomer Example 1.

### Synthesis of Model Emitter 1

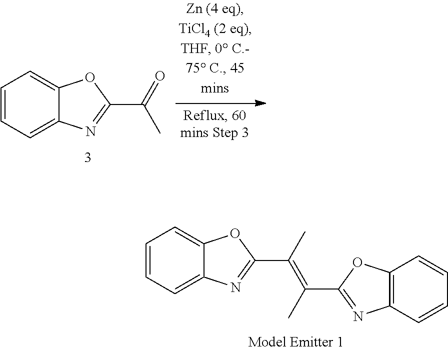 [SMILES: CC(=O)c1nc2ccccc2o1 ; C/C(=C(/C)c1nc2ccccc2o1)c1nc2ccccc2o1]

TiCl₄ (7.05 g, 37.2 mmol) was added to Zinc Powder (4.86 g, 74.4 mmol) in THF (90 mL) at 0° C. in a 500 mL round-bottomed flask connected to a magnetic stirrer, condenser, oil-bath and nitrogen bubbler.

The reaction mixture was heated to 75° C. with stirring for 45 minutes and then cooled to 25° C. To the reaction mixture was added 1-(1,3-benzoxazol-2-yl)ethan-1-one (Intermediate 3, 3 g, 18.6 mmol) in THF (30 mL) at 25° C. The reaction mixture was heated to reflux and stirred for 60 minutes and allowed to cool. The reaction mixture was then quenched with water (100 mL) and extracted with ethyl acetate (100 mL). The organic layer was separated and the volatiles removed to give a solid. The solid was washed three times with hexane, dissolved in acetonitrile and filtered. The filtrate was purified by column chromatography using ethyl acetate:hexane eluent and washed with hexane to afford the E isomer at purity of 99.06% by HPLC. The retentate from the filtration in acetonitrile was dissolved in dichloromethane, passed through celite and the volatiles removed to afford the Z isomer at 99.68% purity.

### Solution Photoluminescence

A solution of 50% (w/v) Monomer Example 1 and 5% (w/v) irgacure 184 (1-Hyrdoxycyclohexyl phenyl ketone) was made up in chloroform. Care was taken to prepare the solution under yellow lighting at all times and solution was stored in an amber vial. For a control experiment, the Irgacure was omitted.

A cell was constructed using a standard 75 mm×25 mm microscope slide as a base, a 2-sided adhesive gasket as the walls, and a 40 mm×25 mm coverslip (150 m thickness) as the top. The adhesive gasket was laser cut from grace bio labs secureSeal™ adhesive sheets (120 μm thick), the coverslip had two portholes laser cut into the ends to allow filling of the solution with a pipette. After filling of the cell with the solution the portholes were sealed with grace biolabs adhesive seal tabs.

For measurement, an Olympus BX60 upright epifluorescence microscope was used with a filter set utilising the 365 nm UV line from a mercury lamp as an excitation source. The camera port on the microscope was connected by fiber optic cable to an ocean optics USB2000+ diode array spectrometer. To measure the reaction of the solution to UV excitation the Spectrometer was set up to integrate the spectrometer counts between 400 nm and 500 nm and take measurements every second. Then the sample was placed under the microscope, the shutter was opened and the spectrometer started recording simultaneously. The UV light intensity from the microscope was measured at 7.3 mW/cm². Samples with and without initiator were exposed.

FIG. 2 shows a more than 20 fold increase in photoluminescence following irradiation of the solution containing Monomer Example 1 and the initiator. In contrast, the control solution containing no initiator showed no change following irradiation.

1. A light-emitting polymer comprising a repeat unit of formula (I): 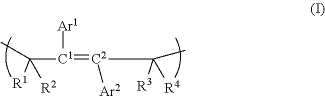
wherein:
R¹-R⁴ are each independently H or a substituent; and
Ar¹ and Ar² are each independently an aromatic or heteroaromatic group selected from formulae (IIa) and (IIb): 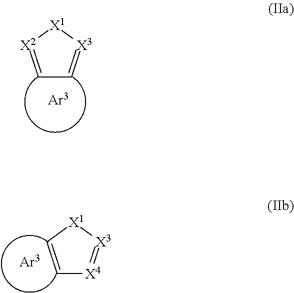
wherein:
X¹ is O, S, NR⁵ or PR⁵;
X²-X⁴ independently in each occurrence is selected from CR⁶ and N;
R⁵ is H or a substituent;
R⁶ independently in each occurrence is H, a substituent or a direct bond to C¹ or C²;
Ar³ is an aromatic or heteroaromatic group; and
either:
one of X²-X⁴ is CR⁶ wherein R⁶ is a direct bond to C¹ or C²; or
an aromatic carbon atom of Ar³ is bound directly to C¹ or C².

2. The polymer according to claim 1 wherein R¹-R⁴ are each H.

3. The polymer according to claim 1 wherein Ar³ is benzene which is unsubstituted or substituted with one or more substituents.

4. The polymer according to claim 1 wherein the polymer is a copolymer comprising a repeat unit of formula (I) and at least one co-repeat unit.

5. The polymer according to claim 4 wherein the polymer comprises a co-repeat unit of formula (III): 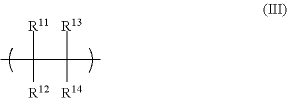
wherein R¹¹-R¹⁴ independently in each occurrence is H or a substituent.

6. A method of forming a polymer according to claim 1 comprising polymerisation of a monomer of formula (Im): 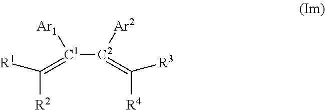
wherein Ar¹, Ar² and R¹-R⁴ are as defined in claim 1.

7. The method according to claim 6 wherein the polymerisation is a radical polymerisation.

8. The method according to claim 6 wherein the polymerisation is an ionic polymerisation.

9. A composition comprising:
a compound of formula (Im) according to claim 6; and
an initiator for forming, upon irradiation with light of a write wavelength, a reactive material for initiating polymerisation of the compound of formula (Im).

10. A composition according to claim 9, the composition further comprising an inhibitor for inhibiting formation of the reactive material upon irradiation with light of a write inhibition wavelength.

11. A method of recording data to a layer of a recording medium comprising a composition according to claim 9, the method comprising irradiating the composition with a first light beam having the write wavelength.

12. The method according to claim 11 wherein the composition is a compound of formula (Im) further comprising an inhibitor for inhibiting formation of the reactive material upon irradiation with light of a write inhibition wavelength and wherein: the composition is irradiated with a second light beam having the write inhibition wavelength; the second light beam has a central area and a surrounding area; an intensity of the second light beam in the central area is lower than an intensity of the second light beam in the surrounding area; the first light beam extends across the central area; and the surrounding area of the second light beam surrounds the first light beam.
